(19) United States
(12) Patent Application Publication
(10) Pub. No.: US 2024/0217062 A1
(43) Pub. Date: Jul. 4, 2024

(54) SUBSTRATE POLISHING APPARATUS, SUBSTRATE PROCESSING APPARATUS, METHOD, AND STORAGE MEDIUM

(71) Applicant: EBARA CORPORATION, Tokyo (JP)

(72) Inventors: Masashi KABASAWA, Tokyo (JP); Yoichi SHIOKAWA, Tokyo (JP); Keita YAGI, Tokyo (JP); Toshimitsu SASAKI, Tokyo (JP); Kohei EGAWA, Tokyo (JP)

(21) Appl. No.: 18/395,059

(22) Filed: Dec. 22, 2023

(30) Foreign Application Priority Data
Dec. 28, 2022 (JP) 2022-211162

(51) Int. Cl. B24B 53/017; B24B 37/04; B24B 49/00

(52) U.S. Cl. CPC B24B 53/017; B24B 37/042; B24B 49/006

(57) ABSTRACT

An object of the present disclosure is to more appropriately control the moving speed of a dresser. A substrate polishing apparatus includes a dresser that moves in a plurality of scan areas set on a polishing member, and a moving speed calculation unit that calculates a moving speed of the dresser in each of the scan areas based on an evaluation index including a deviation from a stay time of the dresser in each of the scan areas on a basis of a previous recipe.

### CROSS-REFERENCE TO RELATED APPLICATION

This application claims the benefit of Japanese Patent Applications No. 2022-211162, filed Dec. 28, 2022, which is hereby incorporated by reference herein in its entirety.

### BACKGROUND

### Technical Field

The present disclosure relates to a substrate polishing apparatus, a substrate processing apparatus, a method, and a storage medium.

### Related Art

As semiconductor devices are highly integrated, wiring of circuits becomes finer, and dimensions of devices to be integrated also becomes finer. In this regard, a process of polishing a wafer having a film of metal or the like formed on a surface thereof is required to planarize the surface of the wafer. One of the methods of planarization is polishing with a chemical mechanical polishing (CMP) apparatus. The chemical mechanical polishing apparatus includes a polishing member (e.g., polishing cloth and polishing pad) and a retainer (e.g., top ring, polishing head, and chuck) that retains a polishing target such as a wafer. Then, the surface of the polishing target (surface to be polished) is pressed against the surface of the polishing member, and the polishing member and the polishing target are relatively moved with a polishing liquid (e.g., abrasive liquid, chemical liquid, slurry, and pure water) being supplied between the polishing member and the polishing target, so that the surface of the polishing target is polished flat.

As a material of the polishing member used in such a chemical mechanical polishing apparatus, a foamed resin or a nonwoven fabric is commonly used. The surface of the polishing member has minute irregularities and the minute irregularities act as chip pockets effective for preventing clogging and reducing polishing resistance. However, continuous use of the polishing member to polish the polishing target causes crushing of minute irregularities on the surface of the polishing member, and thus lowers the polishing rate of the polishing target. In this regard, the surface of the polishing member is subjected to dressing (dressed) by a dresser having a large number of electrodeposited abrasive grains such as diamond grains to regenerate minute irregularities on the surface of the polishing member.

To dress the polishing member, for example, dressing is performed with the dressing surface of a rotating dresser pressed against a rotating polishing member while the dresser is being moved (reciprocated or swung arcuately or linearly). At the time of dressing of the polishing member, the surface of the polishing member is shaved although the amount is small. Thus, if dressing is not appropriately performed, inappropriate undulation occurs on the surface of the polishing member, and thus causes variations in the polishing rate of the polishing target. Since variations in the polishing rate lead to a polishing failure, appropriate dressing is necessary so that inappropriate undulation will not occur on the surface of the polishing member. That is, it is necessary to perform dressing under appropriate dressing conditions such as an appropriate rotation speed of the polishing member, an appropriate rotation speed of the dresser, an appropriate dressing load, and an appropriate moving speed of the dresser to avoid variations in the cut rate of the polishing member and to prevent occurrence of inappropriate undulation.

### CITATION LIST

### Patent Literature

Patent Literature 1: JP 2022-32201 A

### SUMMARY

### Technical Problem

An object of the present disclosure is to more appropriately control the moving speed of a dresser.

### Solution to Problem

A substrate polishing apparatus according to a first aspect includes: a dresser that moves in a plurality of scan areas set on a polishing member; and a moving speed calculation unit that calculates a moving speed of the dresser in each of the scan areas based on an evaluation index including a deviation from a stay time of the dresser in each of the scan areas on the basis of a previous recipe.

The substrate polishing apparatus according to a second aspect is the substrate polishing apparatus according to the first aspect, in which the stay time corresponds to the moving speed of the dresser.

The substrate polishing apparatus according to a third aspect is the substrate polishing apparatus according to the first or second aspect, in which the evaluation index includes a weighting coefficient for the deviation.

The substrate polishing apparatus according to a fourth aspect is the substrate polishing apparatus according to the third aspect, in which as the weighting coefficient increases, an update amount of the moving speed of the dresser decreases.

The substrate polishing apparatus according to a fifth aspect is the substrate polishing apparatus according to any one of the first to fourth aspects, in which the evaluation index further includes at least one of a deviation from a target cut amount, a deviation from a stay time in a reference recipe, or a speed difference between adjacent scan areas.

The substrate polishing apparatus according to a sixth aspect is the substrate polishing apparatus according to any one of the first to fifth aspects further including: a height detection unit that measures a surface height of the polishing member in each of the scan areas; and a cut rate calculation unit that calculates a cut rate of the polishing member in each of the scan areas.

The substrate polishing apparatus according to a seventh aspect is the substrate polishing apparatus according to the sixth aspect, in which a height profile of the polishing member is estimated on the basis of the cut rate.

The substrate polishing apparatus according to an eighth aspect is the substrate polishing apparatus according to any one of the first to seventh aspects, in which the moving speed calculation unit calculates the moving speed of the dresser by performing optimization calculation that minimizes the evaluation index.

The substrate polishing apparatus according to a ninth aspect is the substrate polishing apparatus according to the eighth aspect, in which the optimization calculation is quadratic programming.

A substrate processing apparatus according to a tenth aspect includes the substrate polishing apparatus according to any one of the first to ninth aspects.

A method according to an eleventh aspect is a method for moving a dresser in a plurality of scan areas set on a polishing member, the method including calculating a moving speed of the dresser in each of the scan areas based on an evaluation index including a deviation from a stay time of the dresser in each of the scan areas on the basis of a previous recipe.

A storage medium according to a twelfth aspect is a computer-readable storage medium storing a program for causing a computer to execute a method for moving a dresser in a plurality of scan areas set on a polishing member, the method including calculating a moving speed of the dresser in each of the scan areas based on an evaluation index including a deviation from a stay time of the dresser in each of the scan areas on the basis of a previous recipe.

### Advantageous Effects of Invention

According to the present disclosure, the moving speed of a dresser can be more appropriately controlled.

### BRIEF DESCRIPTION OF DRAWINGS

FIG. 1 is a schematic view illustrating a polishing apparatus for polishing a substrate such as a wafer;

FIG. 2 is a plan view schematically illustrating a dresser and a polishing pad;

FIG. 3 is a diagram illustrating an example of scan areas set on the polishing pad;

FIG. 4 is an explanatory diagram illustrating a relation between scan areas and monitor areas of the polishing pad;

FIG. 5 is a block diagram illustrating an example of a configuration of a dressing monitoring device;

FIG. 6 is an explanatory diagram illustrating an example of profile transition of a polishing pad height in each scan area;

FIG. 7 is an explanatory diagram illustrating an example of a dresser moving speed and a reference value in each scan area;

FIG. 8 is a flowchart illustrating an example of a procedure for adjusting the moving speed of the dresser;

FIG. 9A is a conceptual diagram of a graph illustrating an example of a relation between the number of processed wafers W and a scan speed (moving speed) of the dresser when a weight k in an evaluation index J is 0; and

FIG. 9B is a conceptual diagram of a graph illustrating an example of a relation between the number of processed wafers W and a scan speed (moving speed) of the dresser when the weight K in the evaluation index J is greater than 0.

### DETAILED DESCRIPTION

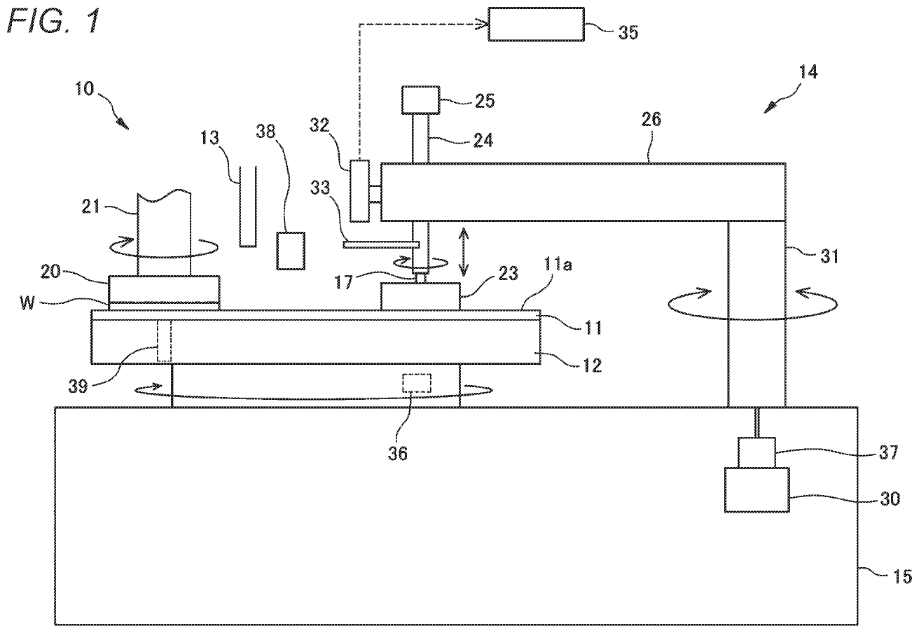

Hereinafter, an embodiment of the present disclosure will be described with reference to the drawings. FIG. 1 is a schematic view illustrating a polishing apparatus for polishing a substrate such as a wafer. The polishing apparatus is provided in a substrate processing apparatus capable of performing a series of processes of polishing, cleaning, and drying a wafer.

As illustrated in FIG. 1, the polishing apparatus includes a polishing unit 10 for polishing a wafer W, a polishing table 12 for holding a polishing pad (polishing member) 11, a polishing liquid supply nozzle 13 for supplying polishing liquid onto the polishing pad 11, and a dressing unit 14 for conditioning (dressing) the polishing pad 11 used for polishing the wafer W. The polishing unit 10 and the dressing unit 14 are installed on a base 15.

The polishing unit 10 includes a top ring (substrate retainer) 20 connected to a lower end of a top ring shaft 21. The top ring 20 is configured to retain the wafer W on its lower surface by vacuum suction. The top ring shaft 21 is rotated by driving of a motor (not illustrated), and the rotation of the top ring shaft 21 rotates the top ring 20 and the wafer W. The top ring shaft 21 is configured to move up and down with respect to the polishing pad 11 by a vertical movement mechanism (not illustrated) (e.g., a vertical movement mechanism including a servomotor and a ball screw).

The polishing table 12 is connected to a motor 22 disposed below the polishing table. The polishing table 12 is rotated about its axis by the motor 22. The polishing pad 11 is attached to the upper surface of the polishing table 12, and the upper surface of the polishing pad 11 constitutes a polishing surface 11a for polishing the wafer W.

The wafer W is polished in the following manner. The top ring 20 and the polishing table 12 are rotated and polishing liquid is supplied onto the polishing pad 11. In this state, the top ring 20 retaining the wafer W is lowered, and the wafer W is pressed against the polishing surface 11a of the polishing pad 11 by a pressurizing mechanism (not illustrated) including an airbag installed in the top ring 20. The wafer W and the polishing pad 11 come into sliding contact with each other in the presence of the polishing liquid, whereby the surface of the wafer W is polished and planarized.

The dressing unit 14 includes a dresser 23 configured to be in contact with the polishing surface 11a of the polishing pad 11, a dresser shaft 24 connected to the dresser 23, an air cylinder 25 provided at an upper end of the dresser shaft 24, and a dresser arm 26 that rotatably supports the dresser shaft 24. Abrasive grains such as diamond grains are fixed to the lower surface of the dresser 23. The lower surface of the dresser 23 is included in a dressing surface for dressing the polishing pad 11.

The dresser shaft 24 and the dresser 23 are vertically movable with respect to the dresser arm 26. The air cylinder 25 is a device that applies a dressing load to the dresser 23 and to the polishing pad 11. The dressing load can be adjusted by the air pressure supplied to the air cylinder 25.

The dresser arm 26 is driven by a motor 30 and configured to swing about a support shaft 31. The dresser shaft 24 is rotated by a motor (not illustrated) installed in the dresser arm 26, and the rotation of the dresser shaft 24 rotates the dresser 23 about the axis thereof. The air cylinder 25 presses the dresser 23 against the polishing surface 11a of the polishing pad 11 with a predetermined load via the dresser shaft 24.

Conditioning of the polishing surface 11a of the polishing pad 11 is performed in the following manner. The polishing table 12 and the polishing pad 11 are rotated by the motor 22, and dressing liquid (e.g., pure water) is supplied from a dressing liquid supply nozzle (not illustrated) to the polishing surface 11a of the polishing pad 11. Furthermore, the dresser 23 is rotated about the axis thereof. The dresser 23 is pressed against the polishing surface 11a by the air cylinder 25, and the lower surface (dressing surface) of the dresser 23 is brought into sliding contact with the polishing surface 11a. In this state, the dresser arm 26 is turned to swing the dresser 23 on the polishing pad 11 in the substantially radial direction of the polishing pad 11. The polishing pad 11 is shaved by the rotating dresser 23, and thus conditioning the polishing surface 11a is performed.

A pad height sensor (surface height measuring device) 32 for measuring the height of the polishing surface 11a is fixed to the dresser arm 26. A sensor target 33 facing the pad height sensor 32 is fixed to the dresser shaft 24. The sensor target 33 moves up and down integrally with the dresser shaft 24 and the dresser 23, but the position of the pad height sensor 32 in the vertical direction is fixed. The pad height sensor 32 is a displacement sensor, and can indirectly measure the height of the polishing surface 11a (thickness of the polishing pad 11) by measuring the displacement of the sensor target 33. Since the sensor target 33 is connected to the dresser 23, the pad height sensor 32 can measure the height of the polishing surface 11a during conditioning of the polishing pad 11.

The height of the polishing surface 11a is measured by the pad height sensor 32 in a plurality of predetermined regions (monitor areas) divided in the radial direction of the polishing pad. The pad height sensor 32 indirectly measures the polishing surface 11a from a position in the vertical direction of the dresser 23 in contact with the polishing surface 11a. Thus, the average height of the polishing surface 11a in a region (certain monitor area) in contact with the lower surface (dressing surface) of the dresser 23 is measured by the pad height sensor 32, and the height of the polishing pad is measured in a plurality of monitor areas, whereby the profile of the polishing pad (sectional shape of the polishing surface 11a) can be obtained. As the pad height sensor 32, any type of sensor such as a linear scale sensor, a laser sensor, an ultrasonic sensor, or an eddy current sensor can be used.

The pad height sensor 32 is connected to a dressing monitoring device 35, and an output signal (i.e., a measured value of the height of the polishing surface 11a) of the pad height sensor 32 is transmitted to the dressing monitoring device 35. The dressing monitoring device 35 has a function of acquiring a profile of the polishing pad 11 from the measured value of the height of the polishing surface 11a and further determining whether conditioning of the polishing pad 11 is performed properly.

The polishing apparatus includes a table rotary encoder 36 that measures the rotation angle of the polishing table 12 and the polishing pad 11, and a dresser rotary encoder 37 that measures the turning angle of the dresser 23. The table rotary encoder 36 and the dresser rotary encoder 37 are absolute encoders that measure absolute values of angles. These rotary encoders 36 and 37 are connected to the dressing monitoring device 35, and the dressing monitoring device 35 can acquire the rotation angle of the polishing table 12 and the polishing pad 11, and further the turning angle of the dresser 23 at the time of height measurement of the polishing surface 11a by the pad height sensor 32.

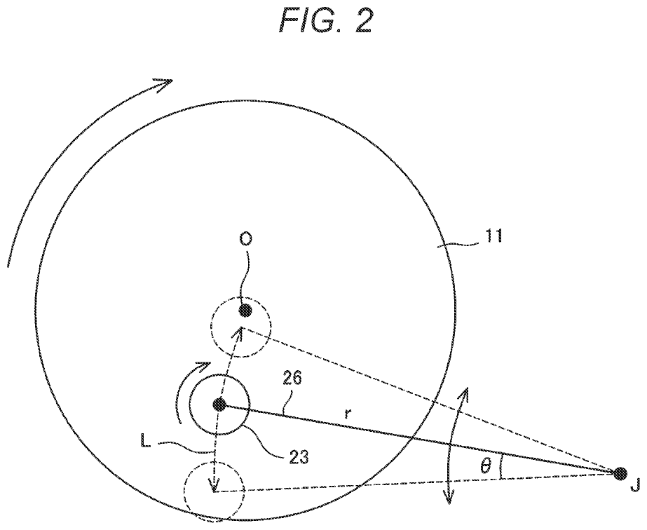

The dresser 23 is connected to the dresser shaft 24 via a universal joint 17. The dresser shaft 24 is connected to a motor (not illustrated). The dresser shaft 24 is rotatably supported by the dresser arm 26, and the dresser arm 26 is configured to swing the dresser 23 in the radial direction of the polishing pad 11 as illustrated in FIG. 2 with the dresser 23 in contact with the polishing pad 11. The universal joint 17 is configured to transmit the rotation of the dresser shaft 24 to the dresser 23 while allowing tilting of the dresser 23. The dresser 23, the universal joint 17, the dresser shaft 24, the dresser arm 26, a rotation mechanism (not illustrated), and the like constitute the dressing unit 14. The dressing monitoring device 35 that calculates a sliding distance and a sliding speed of the dresser 23 is electrically connected to the dressing unit 14. As the dressing monitoring device 35, a dedicated or general-purpose computer can be used.

Abrasive grains such as diamond grains are fixed to the lower surface of the dresser 23. The part to which the abrasive grains are fixed is included in the dressing surface for dressing the polishing surface of the polishing pad 11. As an aspect of the dressing surface, it is possible to apply a circular dressing surface (dressing surface with abrasive grains fixed to the entire lower surface of the dresser 23), a ring-shaped dressing surface (dressing surface with abrasive grains fixed to the peripheral part of the lower surface of the dresser 23) or a plurality of circular dressing surfaces (dressing surfaces with abrasive grains fixed to the surfaces of a plurality of pellets of a small diameter arranged at substantially equal intervals around the center of the dresser 23). The dresser 23 in the present embodiment has a circular dressing surface.

When dressing of the polishing pad 11 is performed, as illustrated in FIG. 1, the polishing pad 11 is rotated at a predetermined rotation speed in the direction of the arrow, and the dresser 23 is rotated at a predetermined rotation speed in the direction of the arrow by a rotation mechanism (not illustrated). Then, in this state, the dressing surface (the surface on which the abrasive grains are arranged) of the dresser 23 is pressed against the polishing pad 11 with a predetermined dressing load to dress the polishing pad 11. In addition, the dresser arm 26 swings the dresser 23 on the polishing pad 11, thereby dressing a region (polishing region, or a region for polishing a polishing target such as a wafer) of the polishing pad 11 used for polishing.

Since the dresser 23 is connected to the dresser shaft 24 via the universal joint 17, the dressing surface of the dresser 23 appropriately abuts on the polishing pad 11 if the dresser shaft 24 is slightly inclined with respect to the surface of the polishing pad 11. A pad roughness measuring device 38 for measuring the surface roughness of the polishing pad 11 is disposed above the polishing pad 11. As the pad roughness measuring device 38, a known non-contact type surface roughness measuring device such as an optical type device can be used. The pad roughness measuring device 38 is connected to the dressing monitoring device 35, and a measured value of the surface roughness of the polishing pad 11 is transmitted to the dressing monitoring device 35.

A film thickness sensor (film thickness measuring device) 39 for measuring the film thickness of the wafer W is disposed in the polishing table 12. The film thickness sensor 39 is disposed facing the surface of the wafer W retained by the top ring 20. The film thickness sensor 39 is a film thickness measuring device that measures the film thickness of the wafer W while moving across the surface of the wafer W with the rotation of the polishing table 12. As the film thickness sensor 39, a non-contact type sensor such as an eddy current sensor or an optical sensor can be used. The measured value of the film thickness is transmitted to the dressing monitoring device 35. The dressing monitoring device 35 is configured to generate a film thickness profile (distribution of the film thickness along the radial direction of the wafer W) of the wafer W from the measured value of the film thickness.

Next, swinging of the dresser 23 will be described with reference to FIG. 2. The dresser arm 26 turns clockwise and counterclockwise about point J by a predetermined angle. The position of point J corresponds to the center position of the support shaft 31 illustrated in FIG. 1. As the dresser arm 26 turns, the rotation center of the dresser 23 swings in the radial direction of the polishing pad 11 within a range indicated by arc L.

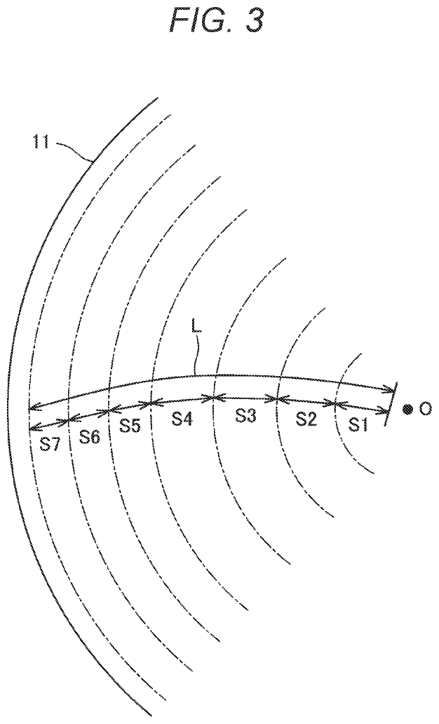

FIG. 3 is an enlarged view of the polishing surface 11a of the polishing pad 11. As illustrated in FIG. 3, the swing range (swing width L) of the dresser 23 is divided into a plurality of (seven in the example of FIG. 3) scan areas (swing sections) S1 to S7. These scan areas S1 to S7 are virtual sections set in advance on the polishing surface 11a, and are arranged along the swing direction of the dresser 23 (i.e., substantially radial direction of the polishing pad 11). The dresser 23 performs dressing of the polishing pad 11 while moving across the scan areas S1 to S7. The lengths of the scan areas S1 to S7 may be the same as or different from each other.

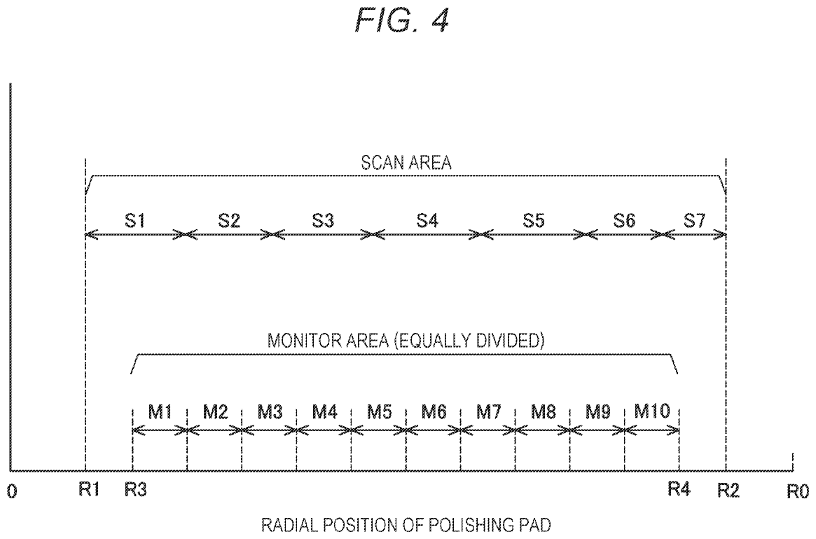

FIG. 4 is an explanatory diagram illustrating a positional relation between the scan areas S1 to S7 and the monitor areas M1 to M10 of the polishing pad 11, and the horizontal axis of the drawing represents the distance from the center of the polishing pad 11. In the present embodiment, seven scan areas and ten monitor areas are set as an example, but the number of scan areas and monitor areas can be changed as appropriate. In addition, since it is difficult to control the pad profile in the regions from both ends of the scan area to the width corresponding to the radius of the dresser 23, monitor exclusion widths are provided on the inner side (region between R1 and R3 in FIG. 4) and the outer side (region between R4 and R2 in FIG. 4), but the exclusion width is not necessarily provided. That is, the scan areas and the monitor areas may be the same.

The moving speed of the dresser 23 when swinging on the polishing pad 11 is set in advance for each of the scan areas S1 to S7, and can be adjusted as appropriate. The distribution of the moving speed of the dresser 23 represents the moving speed of the dresser 23 in each of the scan areas S1 to S7.

The moving speed of the dresser 23 is one of the determinants of the pad height profile of the polishing pad 11. The cut rate of the polishing pad 11 represents the amount (thickness) of the polishing pad 11 shaved by the dresser 23 per unit time. When the dresser is moved at a constant speed, usually, the thickness of the polishing pad 11 shaved in each scan area is different, and thus the numerical value of the cut rate differs for each scan area. However, since it is usually preferable to maintain the initial shape of the pad profile, the moving speed is adjusted to reduce the difference in the shaving amount in each scan area.

Here, increasing the moving speed of the dresser 23 means shortening the stay time of the dresser 23 on the polishing pad 11, that is, reducing the shaving amount of the polishing pad 11. On the other hand, reducing the moving speed of the dresser 23 means increasing the stay time of the dresser 23 on the polishing pad 11, that is, increasing the shaving amount of the polishing pad 11. Therefore, increasing the moving speed of the dresser 23 in a certain scan area can reduce the shaving amount in the scan area, and reducing the moving speed of the dresser 23 in a certain scan area can increase the shaving amount in the scan area. With this configuration, the pad height profile of the entire polishing pad can be adjusted.

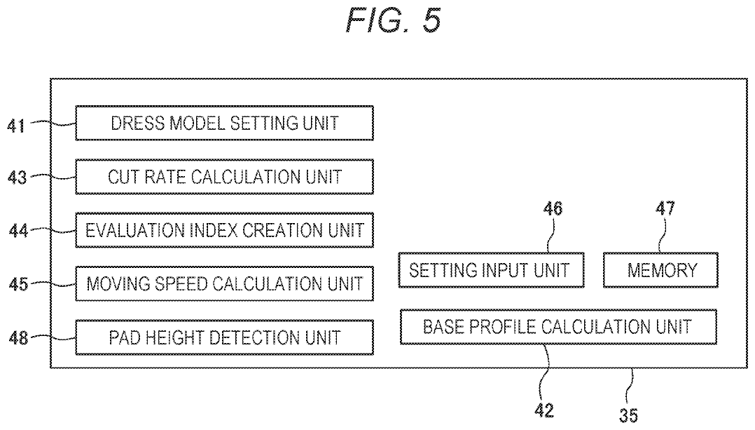

As illustrated in FIG. 5, the dressing monitoring device 35 includes a dress model setting unit 41, a base profile calculation unit 42, a cut rate calculation unit 43, an evaluation index creation unit 44, a moving speed calculation unit 45, a setting input unit 46, a memory 47, and a pad height detection unit 48, and acquires the profile of the polishing pad 11 and sets the moving speed of the dresser 23 in the scan areas to be optimal at predetermined timing.

The dress model setting unit 41 sets a dress model S for calculating the wear amount of the polishing pad 11 in the scan areas. The dress model S is a real number matrix of m rows and n columns where the number of divisions of monitor areas is m (10 in the present embodiment) and the number of divisions of scan areas is n (7 in the present embodiment), and is determined by various parameters described later. When the scan areas and the monitor areas are the same, the dress model S is S=[s₁, s₂, . . . , sₙ].

When the scan speed of the dresser in each scan area set on the polishing pad 11 is V=[v₁, v₂, . . . , vₙ] and the width of each scan area is W=[w₁, w₂, . . . , wₙ], the stay time of (the center of) the dresser in each scan area is represented by T=W/V=[w₁/v₁, w₂/v₂, . . . , wₙ/vₙ]. In this case, when the pad wear amount in each monitor area is U=[u₁, u₂, . . . , uₙ] and the above-described dress model S and the stay time T in each scan area are used, the pad wear amount U is calculated by performing the matrix operation of

$$U = ST .$$

To derive the dress model matrix S, for example, elements of 1) a cut rate model, 2) a dresser diameter, and 3) scan speed control are taken into consideration and can be combined as appropriate. The cut rate model is set on the assumption that the elements of the dress model matrix S are proportional to the stay time in the monitor areas or proportional to the scratch distance (moving distance).

Furthermore, regarding the dresser diameter, the elements of the dress model matrix S are set on the assumption that the diameter of the dresser is taken into consideration (the polishing pad is worn according to the same cut rate over the entire effective area of the dresser) or not into consideration (the polishing pad is worn according to the cut rate only at the center position of the dresser). When the dresser diameter is taken into consideration, an appropriate dress model can be defined for a dresser to which diamond grains are applied in a ring shape, for example. Furthermore, regarding the scan speed control, the elements of the dress model matrix S are set according to whether the change in the moving speed of the dresser is stepwise or sloped. By combining these parameters as appropriate, it is possible to calculate a cut amount more matching the actual state from the dress model S and obtain a proper profile prediction value.

The pad height detection unit 48 detects the pad height in each monitor area by associating the height data of the polishing pad continuously measured by the pad height sensor 32 with the measurement coordinate data on the polishing pad.

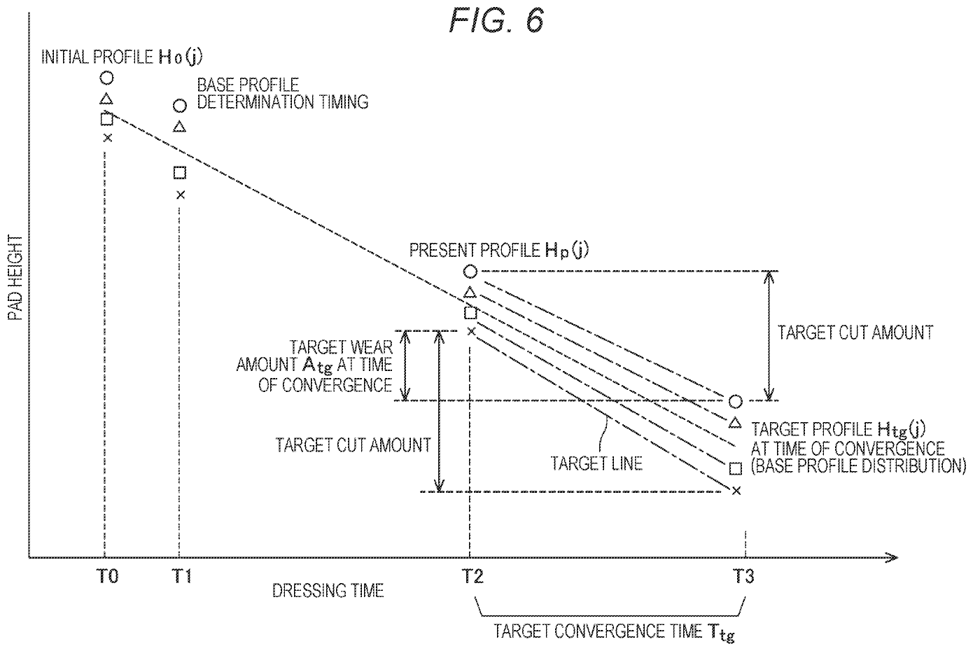

The base profile calculation unit 42 calculates a target profile (base profile) of the pad height at the time of convergence (see FIG. 6). The base profile is used to calculate a target cut amount to be used by the moving speed calculation unit 45 described later. The base profile may be calculated on the basis of the height distribution (Diff (j)) of the polishing pad in the initial state of the pad and the measured pad height, or may be given as a set value. When the base profile is not set, the base profile calculation unit 42 may calculate a target cut amount at which the shape of the polishing pad becomes flat.

A base of the target cut amount is calculated by the following expression using a pad height profile Hₚ(j) [j=1, 2 . . . m] indicating the pad height for each monitor area at the present time and a separately set target wear amount A_{tg} at the time of convergence.

$$min \{ {H}_{p} ( j ) \} - {A}_{tg}$$

The target cut amount for each monitor area can be calculated by the following expression with the above-described base profile taken into consideration.

$$min \{ {H}_{p} ( j ) \} - {A}_{tg} + Diff ( j )$$

The cut rate calculation unit 43 calculates the cut rate of the dresser in each monitor area. For example, the cut rate may be calculated from the inclination of the change amount of the pad height in each monitor area (change amount of the pad height per unit time).

The evaluation index creation unit 44 optimizes the moving speed of the dresser in each scan area by calculating and correcting the optimal stay time (swing time) in the scan area using an evaluation index to be described later. This evaluation index is an index based on 1) a deviation from the target cut amount, 2) a deviation from the stay time in the reference recipe, 3) a speed difference between adjacent scan areas, and 4) a deviation from the stay time in the previous recipe, and is a function of stay time T=[w₁/v₁, w₂/v₂, . . . , wₙ/vₙ] in each scan area. Then, the moving speed of the dresser is optimized by determining the stay time T in each scan area such that the evaluation index is minimized.

1) Deviation from Target Cut Amount

When the target cut amount of the dresser is U₀=[U₀₁, U₀₂, . . . , U₀ₘ], the deviation from the target cut amount is calculated by obtaining a square value (|U−U₀|²) of a difference from the pad wear amount U (=ST) in each monitor area described above. Note that the target profile for determining the target cut amount can be determined at any timing after the start of use of the polishing pad, or may be determined on the basis of a manually set value.

2) Deviation from Stay Time in Reference Recipe

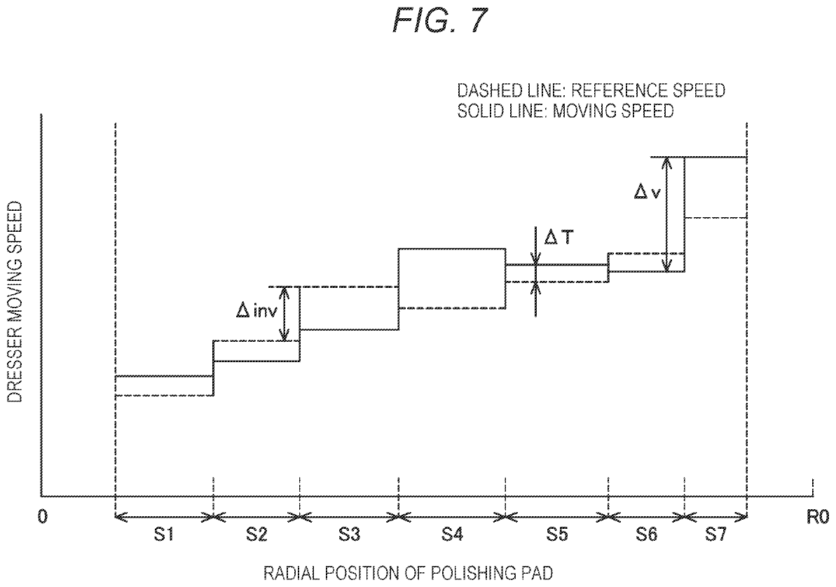

As illustrated in FIG. 7, the deviation from the stay time in the reference recipe can be calculated by obtaining a square value (ΔT²=|T−T₀|²) of the difference (ΔT) between the moving speed (reference speed, or reference stay time T₀) of the dresser based on the reference recipe set in each scan area and the moving speed of the dresser (stay time T of the dresser) in each scan area. Here, the reference speed is a moving speed at which a flat cut rate is expected to be obtained in each scan area, and is a value obtained in advance by experiment or simulation. When the reference speed is obtained by simulation, for example, the reference speed can be obtained on the assumption that the scratch distance (stay time) of the dresser and the cut amount of the polishing pad are proportional to each other. The reference speed may be updated as appropriate according to the actual cut rate during use of the same polishing pad.

### 3) Speed Difference Between Adjacent Scan Areas

The index of the speed difference between adjacent scan areas can be calculated by obtaining a square value (|ΔVᵢₙᵥ|²) of the speed difference between the adjacent scan areas. Here, as illustrated in FIG. 7, either the difference (Δᵢₙᵥ) of the reference speed or the difference (Δᵥ) of the moving speed of the dresser can be used as the speed difference between the scan areas. Since the widths of the scan areas are fixed values, the index of the speed difference depends on the stay time of the dresser in each scan area.

4) Deviation from Stay Time in Previous Recipe

Furthermore, in the polishing apparatus according to the present embodiment, the speed difference from the moving speed of the dresser (stay time T of the dresser) in the previous recipe is reduced to suppress the influence on the surface shape of the polishing pad 11 of the polishing apparatus caused by a rapid change in the moving speed of the dresser. That is, the deviation from the stay time in the previous recipe can be calculated by obtaining a square value (|T−Tₚᵣₑᵥ|²) of the difference between the stay time in the previous recipe and the stay time in the current recipe.

The evaluation index creation unit 44 defines an evaluation index J expressed by the following expression on the basis of these four indices.

$$J = γ {\vert U - {U}_{0} \vert}^{2} + λ {\vert T - {T}_{0} \vert}^{2} + η {\vert Δ {V}_{inv} \vert}^{2} + κ {\vert T - {T}_{prev} \vert}^{2}$$

Here, the first term, the second term, the third term, and the fourth term on the right side of the evaluation index J are indices resulting from, respectively, a deviation from the target cut amount, a deviation from the stay time in the reference recipe, a speed difference between adjacent scan areas, and a deviation from the stay time in the previous recipe, and all depend on the stay time T of the dresser in each scan area.

Then, the moving speed calculation unit 45 obtains the stay time T of the dresser in each scan area by performing optimization calculation such that the value of the evaluation index J takes a minimum value, and corrects the moving speed of the dresser. As a method of the optimization calculation, quadratic programming can be used, but convergence calculation by simulation or proportional-integral-derivative (PID) control may be used.

In the evaluation index J above, γ, λ, n, and k are predetermined weighting values (coefficients), and can be changed as appropriate during use of the same polishing pad. By changing these weighting values, it is possible to adjust an index to be emphasized as appropriate according to the characteristics of the polishing pad and the dresser and the operation status of the apparatus. As the weighting value (coefficient) increases, the update amount of the moving speed of the dresser decreases (fluctuations of the moving speed of the dresser are suppressed).

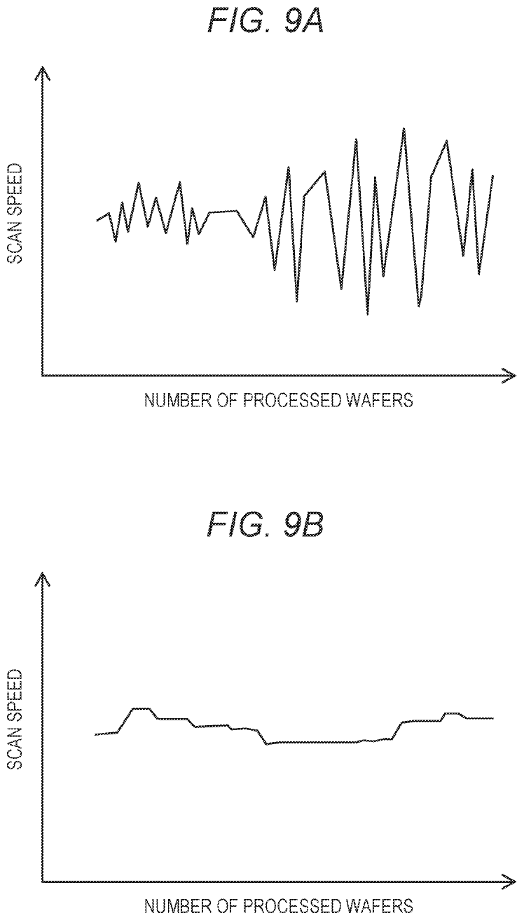

FIG. 9A is a conceptual diagram of a graph illustrating an example of a relation between the number of processed wafers W and a scan speed (moving speed) of the dresser when a weight k in the evaluation index J is 0. As illustrated in FIG. 9A, when the weight k in the evaluation index J is 0, that is, when the “deviation from the stay time in the previous recipe” is not taken into consideration, the fluctuations of the scan speed of the dresser may increase as the number of processed wafers W increases. This is because, for example, the apparent height of the polishing pad increases as the polishing pad absorbs moisture and swells over time. The swelling amount of the polishing pad varies depending on the type of the polishing pad and the use state of the apparatus. When the height of the polishing pad varies due to swelling, the cut rate to be used for calculating the evaluation index J cannot be appropriately calculated. As a result, there is a possibility that the moving speed of the dresser cannot be calculated or the calculated value is an abnormal value.

FIG. 9B is a conceptual diagram of a graph illustrating an example of a relation between the number of processed wafers W and a scan speed (moving speed) of the dresser when the weight k in the evaluation index J is greater than 0 (e.g., K=0.001). As illustrated in FIG. 9B, when the weight k in the evaluation index J is greater than 0, that is, when the “deviation from the stay time in the previous recipe” is taken into consideration, the fluctuations of the scan speed of the dresser are suppressed if the number of processed wafers W increases.

In this manner, the moving speed of the dresser can be appropriately calculated by including the index (the fourth term of the above expression) resulting from the “deviation from the stay time in the previous recipe” in the evaluation index J.

In obtaining the moving speed of the dresser, it is preferable that the total dressing time falls within a predetermined value. Here, the total dressing time is the moving time of the dresser across the entire swing sections (the scan areas S1 to S7 in the present embodiment). When the total dressing time (time required for dressing) increases, other processes such as a polishing process and a conveyance process of the wafer may be affected. Thus, it is preferable to correct the moving speed in each scan area as appropriate so that the value will not exceed a predetermined value. Furthermore, since there are mechanical constraints on the apparatus, it is preferable to set the moving speed of the dresser so that a maximum (and minimum) moving speed of the dresser and a ratio of the maximum speed (minimum speed) to an initial speed also fall within set values.

When appropriate dressing conditions are unknown for a new combination of a dresser and a polishing pad, or when the reference speed (reference stay time T₀) of the dresser is not determined, for example, immediately after replacement of the dresser or the polishing pad, the moving speed calculation unit 45 may determine the evaluation index J (described below) using only the condition of the deviation from the target cut amount and optimize (initially set) the moving speed of the dresser in each scan area.

$$J = {\vert U - {U}_{0} \vert}^{2}$$

The setting input unit 46 is an input device such as a keyboard or a mouse, and is configured to input various parameters such as values of the components of the dress model matrix S, setting of a constraint condition, a cut rate update cycle, and a moving speed update cycle. The memory 47 stores various data such as data of a program for operating the components included in the dressing monitoring device 35, values of the components of the dress model matrix S, a target profile, weighting values of the evaluation index J, and a set value of the moving speed of the dresser.

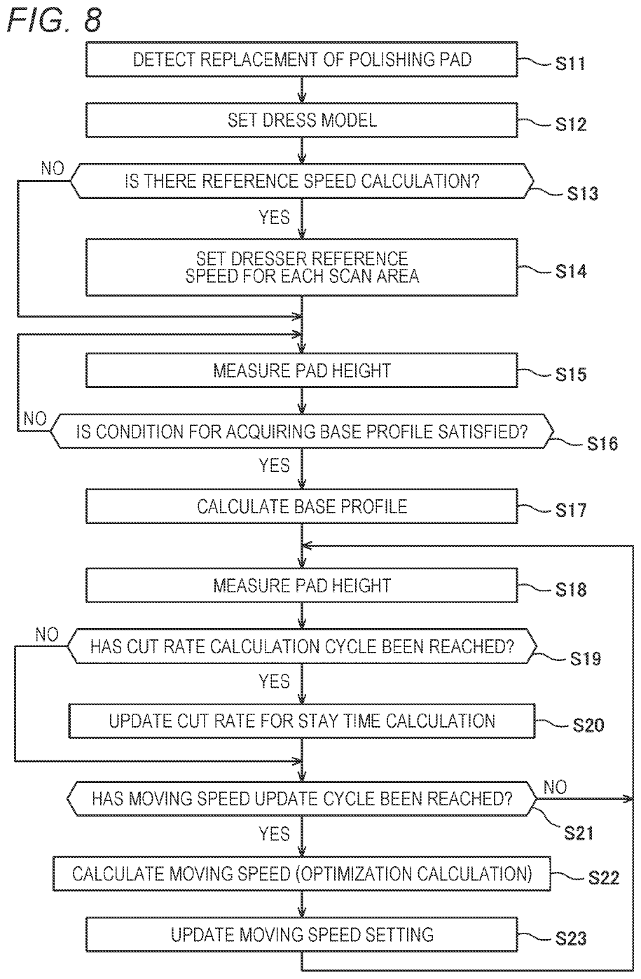

FIG. 8 is a flowchart illustrating a processing procedure for controlling the moving speed of the dresser. When replacement of the polishing pad 11 is detected (step S11), the dress model setting unit 41 derives a dress model matrix S by taking into consideration the parameters of the cut rate model, the dresser diameter, and the scan speed control (step S12). In the case of the same type of pad, the dress model matrix can be continuously used.

It is then determined whether to calculate the reference speed of the dresser (whether there is an input for reference speed calculation from the setting input unit 46) (step S13). When calculating the reference speed, the moving speed calculation unit 45 sets the moving speed (stay time T) of the dresser in each scan area such that the following evaluation index J has a minimum value using the target cut amount U₀ of the dresser and the pad wear amount U in each monitor area (step S14). The calculated reference speed may be set as an initial value of the moving speed.

$$J = {\vert U - {U}_{0} \vert}^{2}$$

Thereafter, when the dressing process is performed on the polishing pad 11 along with the polishing process of the wafer W, the height (pad height) of the polishing surface 11a is measured by the pad height sensor 32 (step S15). Then, it is determined whether a condition for acquiring a base profile (e.g., polishing of a predetermined number of wafers W) is satisfied (step S16), and if the condition is satisfied, the base profile calculation unit 42 calculates a target profile (base profile) of the pad height at the time of convergence (step S17).

Thereafter, when the dressing process is performed on the polishing pad 11 along with the polishing process of the wafer W, the height (pad height) of the polishing surface 11a is measured by the pad height sensor 32 (step S18). Then, it is determined whether a predetermined cut rate calculation cycle (e.g., polishing of a predetermined number of wafers W) has been reached (step S19), and if reached, the cut rate calculation unit 43 calculates the cut rate of the dresser in each scan area (step S20).

Furthermore, it is determined whether the moving speed update cycle (e.g., polishing of a predetermined number of wafers W) of the dresser has been reached (step S21), and if reached, the moving speed calculation unit 45 calculates the stay time of the dresser with which the evaluation index J is minimized and optimizes the dresser moving speed in each scan area (step S22). Then, the value of the optimized moving speed is set, and the moving speed of the dresser is updated (step S23). Thereafter, the processing returns to step S18, and the above procedure is repeated until the polishing pad 11 is replaced.

### OTHER EMBODIMENTS

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

What is claimed is:

1. A substrate polishing apparatus comprising:
a dresser that moves in a plurality of scan areas set on a polishing member; and
a moving speed calculation unit that calculates a moving speed of the dresser in each of the scan areas based on an evaluation index including a deviation from a stay time of the dresser in each of the scan areas on a basis of a previous recipe.

2. The substrate polishing apparatus according to claim 1, wherein the stay time corresponds to the moving speed of the dresser.

3. The substrate polishing apparatus according to claim 1, wherein the evaluation index includes a weighting coefficient for the deviation.

4. The substrate polishing apparatus according to claim 3, wherein as the weighting coefficient increases, an update amount of the moving speed of the dresser decreases.

5. The substrate polishing apparatus according to claim 1, wherein the evaluation index further includes at least one of a deviation from a target cut amount, a deviation from a stay time in a reference recipe, or a speed difference between adjacent scan areas.

6. The substrate polishing apparatus according to claim 1 further comprising:
a height detection unit that measures a surface height of the polishing member in each of the scan areas; and
a cut rate calculation unit that calculates a cut rate of the polishing member in each of the scan areas on a basis of the surface height.

7. The substrate polishing apparatus according to claim 6, wherein a height profile of the polishing member is estimated on a basis of the cut rate.

8. The substrate polishing apparatus according to claim 1, wherein the moving speed calculation unit calculates the moving speed of the dresser by performing optimization calculation that minimizes the evaluation index.

9. The substrate polishing apparatus according to claim 8, wherein the optimization calculation is quadratic programming.

10. A substrate processing apparatus comprising the substrate polishing apparatus according to claim 1.

11. A method for moving a dresser in a plurality of scan areas set on a polishing member, the method comprising
calculating a moving speed of the dresser in each of the scan areas based on an evaluation index including a deviation from a stay time of the dresser in each of the scan areas on a basis of a previous recipe.

12. A non-transitory computer-readable storage medium storing a program for causing a computer to execute a method for moving a dresser in a plurality of scan areas set on a polishing member, the method comprising
calculating a moving speed of the dresser in each of the scan areas based on an evaluation index including a deviation from a stay time of the dresser in each of the scan areas on a basis of a previous recipe.
